(19) United States
(12) Patent Application Publication
(10) Pub. No.: US 2011/0020750 A1
(43) Pub. Date: Jan. 27, 2011

(54) LITHOGRAPHIC IMAGING AND PRINTING WITH WET, POSITIVE-WORKING PRINTING MEMBERS

(75) Inventors: Maria T. Sypek, Belchertown, MA (US); Brian Smith, Westfield, MA (US)

Correspondence Address: GOODWIN PROCTER LLP;PATENT ADMINISTRATOR, 53 STATE STREET, EXCHANGE PLACE, BOSTON, MA, 02109-2881, US

(73) Assignee: Presstek, Inc., Hudson, NH (US)

(21) Appl. No.: 12/508,690

(22) Filed: Jul. 24, 2009

(51) Int. Cl. G03F 7/039; G03F 7/004; G03F 7/20

(52) U.S. Cl. 430/286.1; 430/270.1; 430/302

(57) ABSTRACT

Embodiments of the present invention involve printing members that avoid ablation imaging mechanisms and, as a result, crosslinked topmost layers. Topmost layers as described herein exhibit good thermal stability and durability during printing, but can be cleaned (and thereby removed from unimaged areas) with water or aqueous cleaning fluids following imaging. It is found, in some embodiments, that the viability of certain topmost layers can be critically dependent on the nature of the underlying substrate, e.g., in terms of texture and/or surface volume.

### BACKGROUND OF THE INVENTION

In offset lithography, a printable image is present on a printing member as a pattern of ink-accepting (oleophilic) and ink-rejecting (oleophobic) surface areas. Once applied to these areas, ink can be efficiently transferred to a recording medium in the imagewise pattern with substantial fidelity. In a wet lithographic system, the non-image areas are hydrophilic, and the necessary ink-repellency is provided by an initial application of a dampening fluid to the plate prior to inking. The dampening fluid prevents ink from adhering to the non-image areas, but does not affect the oleophilic character of the image areas. Ink applied uniformly to the wetted printing member is transferred to the recording medium only in the imagewise pattern. Typically, the printing member first makes contact with a compliant intermediate surface called a blanket cylinder which, in turn, applies the image to the paper or other recording medium. In typical sheet-fed press systems, the recording medium is pinned to an impression cylinder, which brings it into contact with the blanket cylinder.

To circumvent the cumbersome photographic development, plate-mounting, and plate-registration operations that typify traditional printing technologies, practitioners have developed electronic alternatives that store the imagewise pattern in digital form and impress the pattern directly onto the plate. Plate-imaging devices amenable to computer control include various forms of lasers.

Current laser-based lithographic systems frequently rely on removal of an energy-absorbing layer from the lithographic plate to create an image. Exposure to laser radiation may, for example, cause ablation—i.e., catastrophic overheating—of the ablated layer in order to facilitate its removal. Because ablation produces airborne debris, ablation-type plates must be designed with imaging byproducts in mind; for example, the plate may be designed so as to trap ablation debris between layers, at least one of which is not removed until after imaging is complete. Such designs can impose constraints in terms of materials that can be used. For example, it may be necessary to use crosslinked topmost layers to reliably retain hot debris; such layers typically require extra processing steps that diminish manufacturing productivity. Moreover, ablation-type plates can require significant laser power to image.

Balancing manufacturability with ease of imaging, as well as consistency and length of print runs, represents a challenging problem.

### SUMMARY OF THE INVENTION

Embodiments of the present invention involve printing members that avoid ablation imaging mechanisms and, as a result, crosslinked topmost layers. Topmost layers as described herein exhibit good thermal stability and durability during printing, but can be cleaned (and thereby removed from unimaged areas) with water or aqueous cleaning fluids following imaging. It is found, in some embodiments, that the viability of certain topmost layers can be critically dependent on the nature of the underlying substrate, e.g., in terms of texture and/or surface volume.

Accordingly, in a first aspect, embodiments of the invention pertain to a lithographic printing member comprising a substrate, a hydrophilic layer disposed above the substrate, an infrared-absorbing layer disposed above the hydrophilic layer, and an ink-accepting surface layer disposed above the absorbing layer. The surface layer and the absorbing layer are unremovable by cleaning with an aqueous fluid until exposed to infrared imaging radiation, whereupon the surface layer and the absorbing layer are rendered removable by cleaning with an aqueous fluid where so exposed. The printing member is desirably imageable at low laser power levels, e.g., by exposure to infrared imaging radiation having a fluence of 180 mJ/cm² or less.

Printing members in accordance with the invention may have a surface layer and an absorbing layer that substantially do not ablate in response to imaging radiation. For example, these layers may may be least 90% unablated following exposure to infrared imaging radiation having a fluence of 180 mJ/cm² or less. In some embodiments, the surface layer and the absorbing layer are at least 98% unablated by exposure to infrared imaging radiation having a fluence of 180 mJ/cm² or less.

As noted above, the viability of certain topmost layers can be critically dependent on the nature of the underlying substrate. Accordingly, in some embodiments, the substrate is a grained metal sheet having (i) a roughness characterized by an Ra value ranging from 0.2 to 0.45 μm and an Rz value less than about 6 μm, and (ii) a surface volume greater than 15,000 μm³. The term “Ra” refers to the average roughness of the surface, i.e., the average distance between the actual surface topography (treating peaks and valleys identically) and the mean surface height, as measured over the entire surface. The term “Rz” refers to the average maximum height of the surface profile, i.e., the arithmetic mean of the roughness depths of consecutive sampling lengths. Z is the sum of the height of the highest peak and the lowest valley depth within a sampling length.

In various embodiments, the surface layer comprises a polymer and a surfactant. The surface layer may be substantially uncrosslinked to permit low-energy imaging followed by aqueous removal. For example, the surface layer may comprise or consist essentially of (i) a novolak, (ii) a polyurethane resin and/or (iii) a terpolymer comprising (or consisting essentially of) vinyl chloride, vinyl acetate, and hydroxyalkyl acrylate. The absorbing layer may comprise or consist essentially of polyvinyl alcohol.

Advantages of printing members in accordance with the invention can include the ability to utilize a simple water rinse after imaging, the absence of developing chemistry and gumming, fabrication that does not involve baking, imaging at low fluence levels without ablation debris, full daylight-safe handling, high imaging resolution, and full ultraviolet (UV) ink compatibility.

In a second aspect, the invention pertains to a method of imaging a lithographic printing member. Embodiments of the method involve providing a lithographic printing member comprising a substrate, a hydrophilic layer disposed above the substrate, an infrared-absorbing layer disposed above the hydrophilic layer, and an ink-accepting surface layer disposed above the absorbing layer. The surface layer and the absorbing layer are unremovable by subjection to an aqueous fluid until exposed to infrared imaging radiation. In accordance with various embodiments, the printing member is exposed to infrared imaging radiation in an imagewise pattern to render the surface layer and the absorbing layer removable by an aqueous fluid where so exposed. The surface layer is then subjected to an aqueous fluid, which removes only exposed portions of the surface layer and the absorbing layer.

In various embodiments, the surface layer and the absorbing layer are substantially unablated by exposure to infrared imaging radiation. For example, the surface layer and the absorbing layer may be at least 90%, or even at least 98%, unablated by exposure to infrared imaging radiation. The infrared imaging radiation is desirably low-power, having, e.g., a fluence of 180 mJ/cm² or less. The aqueous fluid may be, for example, tap water or a mixture of water and a surfactant.

It should be stressed that, as used herein, the term “plate” or “member” refers to any type of printing member or surface capable of recording an image defined by regions exhibiting differential affinities for ink and/or fountain solution. Suitable configurations include the traditional planar or curved lithographic plates that are mounted on the plate cylinder of a printing press, but can also include seamless cylinders (e.g., the roll surface of a plate cylinder), an endless belt, or other arrangement.

Furthermore, the term “hydrophilic” is used in the printing sense to connote a surface affinity for a fluid which prevents ink from adhering thereto. Such fluids include water for conventional ink systems, aqueous and non-aqueous dampening liquids, and the non-ink phase of single-fluid ink systems. Thus, a hydrophilic surface in accordance herewith exhibits preferential affinity for any of these materials relative to oil-based materials.

### DESCRIPTION OF DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 is an enlarged cross-sectional view of a positive-working printing member according to the invention.

FIGS. 2A and 2B illustrate the effect of imaging the printing member illustrated in FIG. 1.

### DETAILED DESCRIPTION

### 1. Imaging Apparatus

An imaging apparatus suitable for use in conjunction with the present printing members includes at least one laser device that emits in the region of maximum plate responsiveness, i.e., whose λₘₐₓ closely approximates the wavelength region where the plate absorbs most strongly. Specifications for lasers that emit in the near infrared (IR) region are fully described in U.S. Pat. No. Re. 35,512 (“the '512 patent”) and U.S. Pat. No. 5,385,092 (“the '092 patent”), the entire disclosures of which are hereby incorporated by reference. Lasers emitting in other regions of the electromagnetic spectrum are well-known to those skilled in the art.

Suitable imaging configurations are also set forth in detail in the '512 and '092 patents. Briefly, laser output can be provided directly to the plate surface via lenses or other beam-guiding components, or transmitted to the surface of a blank printing plate from a remotely sited laser using a fiber-optic cable. A controller and associated positioning hardware maintain the beam output at a precise orientation with respect to the plate surface, scan the output over the surface, and activate the laser at positions adjacent selected points or areas of the plate. The controller responds to incoming image signals corresponding to the original document or picture being copied onto the plate to produce a precise negative or positive image of that original. The image signals are stored as a bitmap data file on a computer. Such files may be generated by a raster image processor (“RIP”) or other suitable means. For example, a RIP can accept input data in page-description language, which defines all of the features required to be transferred onto the printing plate, or as a combination of page-description language and one or more image data files. The bitmaps are constructed to define the hue of the color as well as screen frequencies and angles.

Other imaging systems, such as those involving light valving and similar arrangements, can also be employed; see, e.g., U.S. Pat. Nos. 4,577,932; 5,517,359; 5,802,034; and 5,861,992, the entire disclosures of which are hereby incorporated by reference. Moreover, it should also be noted that image spots may be applied in an adjacent or in an overlapping fashion.

The imaging apparatus can operate on its own, functioning solely as a platemaker, or can be incorporated directly into a lithographic printing press. In the latter case, printing may commence immediately after application of the image to a blank plate, thereby reducing press set-up time considerably. The imaging apparatus can be configured as a flatbed recorder or as a drum recorder, with the lithographic plate blank mounted to the interior or exterior cylindrical surface of the drum. Obviously, the exterior drum design is more appropriate to use in situ, on a lithographic press, in which case the print cylinder itself constitutes the drum component of the recorder or plotter.

In the drum configuration, the requisite relative motion between the laser beam and the plate is achieved by rotating the drum (and the plate mounted thereon) about its axis and moving the beam parallel to the rotation axis, thereby scanning the plate circumferentially so the image “grows” in the axial direction. Alternatively, the beam can move parallel to the drum axis and, after each pass across the plate, increment angularly so that the image on the plate “grows” circumferentially. In both cases, after a complete scan by the beam, an image corresponding (positively or negatively) to the original document or picture will have been applied to the surface of the plate.

In the flatbed configuration, the beam is drawn across either axis of the plate, and is indexed along the other axis after each pass. Of course, the requisite relative motion between the beam and the plate may be produced by movement of the plate rather than (or in addition to) movement of the beam. Examples of useful imaging devices include models of the TRENDSETTER imagesetters (available from Eastman Kodak Company) that utilize laser diodes emitting near-IR radiation at a wavelength of about 830 nm. Other suitable exposure units include the CRESCENT 42T Platesetter (operating at a wavelength of 1064 nm, available from Gerber Scientific, Chicago, Ill.) and the SCREEN PLATERITE 4300 series or 8600 series plate-setter (available from Screen, Chicago, Ill.).

Regardless of the manner in which the beam is scanned, in an array-type system for on-press applications it is generally preferable to employ a plurality of lasers and guide their outputs to a single writing array. The writing array is then indexed, after completion of each pass across or along the plate, a distance determined by the number of beams emanating from the array, and by the desired resolution (i.e., the number of image points per unit length). Off-press applications, which can be designed to accommodate very rapid scanning (e.g., through use of high-speed motors, mirrors, etc.) and thereby utilize high laser pulse rates, can frequently utilize a single laser as an imaging source.

### 2. Lithographic Printing Members

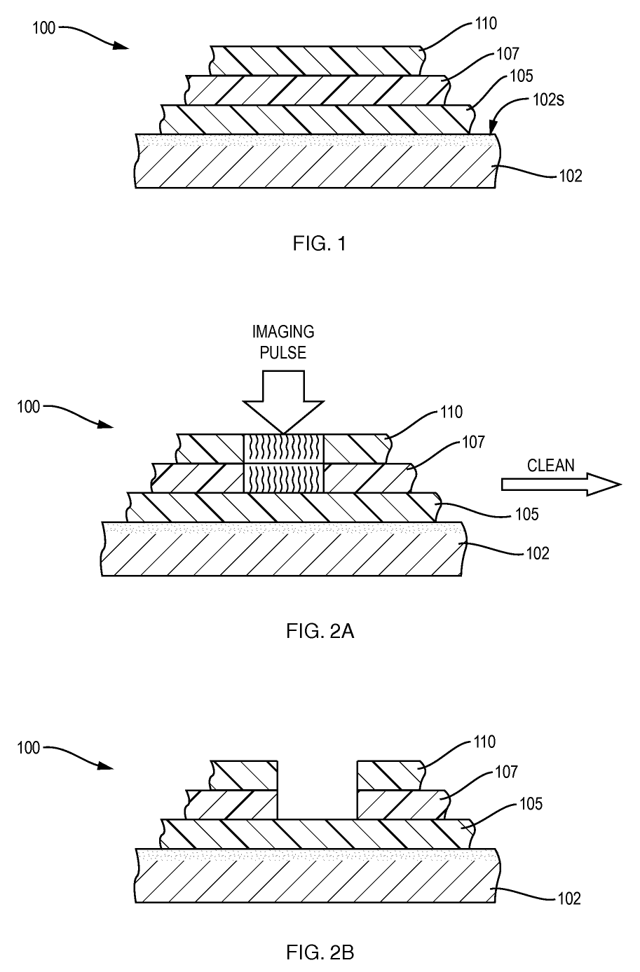

FIG. 1 illustrates a positive-working printing member 100 according to the invention that includes a substrate 102; a hydrophilic polymer layer 105 disposed over (and typically adjacent to) substrate 102; an absorptive layer 107 disposed over (and typically adjacent to) layer 105; and a topmost, ink-accepting layer 110 disposed over (and typically adjacent to) layer 107. Layer 107 is sensitive to imaging (generally IR) radiation as discussed below, and imaging of the printing member 100 (by exposure to IR radiation) heats layer 107, disrupting its polymeric structure and rendering it removable by aqueous cleaning. Moreover, heat is transmitted to layer 110, which disrupts its polymeric structure as well and renders it, too, removable by aqueous cleaning. In some embodiments, the uppermost region of layer 105 is solubilized by heat as well, rendering it partially removable; up to 40% of the thickness of layer 105 may be rendered removable in this way (although usually it is less than 30%, e.g., in the range of 10-20%), and so long as the degree of removal remains in this range, neither plate behavior nor maximum run length appears to be compromised. Importantly, where not exposed to imaging radiation, layers 107, 110 not only remain impervious to aqueous cleaning, but exhibit sufficient durability in a commercial printing environment to withstand at least 25,000 impressions (and in some cases, depending on printing conditions, 100,000 or more impressions). Preferably, layers 107, 110 are rendered removable at low imaging energies, e.g., on the order of 180 mJ/cm² or less.

Most or all of the layers used in the present invention are continuous. The term “continuous” as used herein means that the underlying surface is completely covered with a uniform layer of the deposited material. Each of the layers and its functions are described in detail below.

2.1 Substrate 102

The substrate provides dimensionally stable mechanical support to the printing member. The substrate should be strong, stable, and flexible. One or more surfaces (and, in some cases, bulk components) of the substrate is hydrophilic, and the substrate itself is desirably metal.

In general, metal layers undergo special treatment in order to be capable of accepting fountain solution in a printing environment. Any number of chemical or electrical techniques, in some cases assisted by the use of fine abrasives to roughen the surface, may be employed for this purpose. For example, electrograining involves immersion of two opposed aluminum plates (or one plate and a suitable counterelectrode) in an electrolytic cell and passing alternating current between them. The result of this process is a finely pitted surface topography that readily adsorbs water. See, e.g., U.S. Pat. No. 4,087,341.

A structured or grained surface can also be produced by controlled oxidation, a process commonly called “anodizing.” An anodized aluminum substrate consists of an unmodified base layer and a porous, “anodic” aluminum oxide coating thereover; this coating readily accepts water. However, without further treatment, the oxide coating would lose wettability due to further chemical reaction. Anodized plates are, therefore, typically exposed to a silicate solution or other suitable (e.g., phosphate) reagent that stabilizes the hydrophilic character of the plate surface. In the case of silicate treatment, the surface may assume the properties of a molecular sieve with a high affinity for molecules of a definite size and shape—including, most importantly, water molecules. The treated surface also promotes adhesion to an overlying photopolymer layer. Anodizing and silicate treatment processes are described in U.S. Pat. Nos. 3,181,461 and 3,902,976.

Preferred hydrophilic substrate materials include aluminum that has been mechanically, chemically, and/or electrically grained with subsequent anodization. The surface 102s of substrate 102 has characteristics matched to performance of the overlying layers, as explained in greater detail in the examples below. In various embodiments, substrate 102 has an Ra value ranging from 0.3 to 0.4 μm, an Rz value ranging from 4 to 5 μm, and a surface volume ranging from 16,000 to 18,000 μm³. The thickness of substrate 102 generally ranges from 0.004 to 0.02 inch, with thicknesses in the range 0.005 to 0.012 inch being particularly preferred.

Preferred manufacturing conditions for an electrochemically-grained substrate 102 include short dwell time and high current density. Representative current densities exceed 20 amps/dm² with dwell times shorter than 25 seconds, targeting a charge density above 480 coulombs. Representative grainer conditions include a current density ranging from 25 to 40 amps/dm² and a dwell time ranging from 15 to 20 seconds, targeting charge densities ranging from 500 and 600 coulombs.

2.2 Hydrophilic Layer 105

Suitable materials for layer 105 include hydrophilic polymers, such as polyalkyl ethers, polyhydroxyl compounds, and polycarboxylic acids. For example, a hydrophilic layer 105 may include a fully hydrolyzed polyvinyl alcohol (e.g., CELVOL 305, 325 and 425 sold by Celanese Chemicals, Ltd. Dallas, Tex.), which are usually manufactured by hydrolysis of polyvinyl acetates. The use of fully hydrolyzed alcohol is preferred to assure that residual non-hydrolyzed acetate does not affect the hydrophilic behavior of the surface of layer 105.

Layer 105 is typically applied between 0.05 and 2.5 g/m² using coating techniques known in the art, such as wire-wound rod coating, reverse roll coating, gravure coating, or slot die coating. For example, in particular embodiments, the layer 105 is applied using a wire-round rod, followed by drying in a convection oven. In various embodiments, layer 105 is applied between 0.2 and 2.5 g/m², e.g., 1.0 to 2.0 g/m². In one embodiment, the layer 105 is applied at a dry coating weight of 1.5 g/m².

The durability of layer 105 is preferably enhanced by the use of an inorganic crosslinker, e.g., ammonium zirconium carbonate. In order to ensure a high degree of crosslinking (and thus, a high resistance to water), high concentrations (e.g., 10-20%) of the crosslinker are preferred. A suitable crosslinker is BACOTE 20, sold by MEL Chemicals, Manchester, UK. The top surface of the crosslinked layer 105 preferably contains little or no residual inorganic crosslinker, such that it remains hydrophilic. The use of an inorganic crosslinker rather than an organic crosslinker (e.g., aldehyde) lessens or eliminates VOC emission due to thermal decomposition during the imaging process. However, organic crosslinkers can be used if desired. Suitable crosslinkers include dialdehydes (e.g., the GLYOXAL product sold by Clariant Fine Chemicals, Charlotte, N.C.), melamine formaldehyde (e.g., the CYMEL 303 product sold by Citek), or polyamide epiclhorohydrin (e.g., the POLYCUP 172 product sold by Hercules). The GLYOXAL crosslinker is especially preferred, providing acceptable reduction of solubility at concentration levels of 10% to 20% of solids in the formulation.

The crosslinked layer 105 is not water-soluble, and thus is not fully removed during printing runs. As such, the layer 105 contributes to the mechanical stability of the printing member, enabling the use of an imaging layer comprising a high percentage of metal or consisting essentially of metal. A high ceramic content in the imaging layer, normally required to maximize mechanical stability, is thus not required.

2.3 Absorbing Layer 107

Layer 107 absorbs imaging radiation, which disrupts the layer's polymeric structure and/or de-anchors it from hydrophilic layer 105, rendering it removable by the action of an aqueous fluid. Layer 107 contains an absorbing component (typically, in the case of a pigment, from 30-40% of the dry coating weight), water-soluble crosslinkable binders and/or emulsions (approximately 50% of the dry coating weight), and a crosslinking system (e.g., melamine resin and an acid catalyst, representing from 5-10% of the dry coating weight).

Accordingly, layer 107 may be crosslinked to enhance durability and prevent ablation. Suitable materials for absorptive layer 107 include copolymers of polyvinyl alcohol with polyvinyl pyrrolidone (PVP), and copolymers of polyvinylether (PVE), including polyvinylether/maleic anhydride versions. In some embodiments, layer 107 comprises a hydrophilic polymer and a crosslinking agent. Suitable hydrophilic polymers for layer 107 include, but are not limited to, polyvinyl alcohol and cellulosics. In a preferred embodiment, the hydrophilic polymer is polyvinyl alcohol. The crosslinking agent may be a melamine. In general, the layer 107 is not soluble in water or in a cleaning solution.

Layer 107 is coated typically at a thickness in the range of from about 0.15 to about 0.25 μm, and more preferably in the range of from about 0.18 to about 0.22 μm. After coating, the layer is dried and subsequently cured at a temperature between 135° C. and 185° C.

In the case of IR or near-IR imaging radiation, suitable absorbers include a wide range of dyes and pigments, such as carbon black, nigrosine-based dyes, phthalocyanines (e.g., aluminum phthalocyanine chloride, titanium oxide phthalocyanine, vanadium (IV) oxide phthalocyanine, and the soluble phthalocyanines supplied by Aldrich Chemical Co., Milwaukee, Wis.); naphthalocyanines (see, e.g., U.S. Pat. Nos. 4,977,068; 4,997,744; 5,023,167; 5,047,312; 5,087,390; 5,064,951; 5,053,323; 4,723,525; 4,622,179; 4,492,750; and 4,622,179); iron chelates (see, e.g., U.S. Pat. Nos. 4,912,083; 4,892,584; and 5,036,040); nickel chelates (see, e.g., U.S. Pat. Nos. 5,024,923; 4,921;317; and 4,913,846); oxoindolizines (see, e.g., U.S. Pat. No. 4,446,223); iminium salts (see, e.g., U.S. Pat. No. 5,108,873); and indophenols (see, e.g., U.S. Pat. No. 4,923,638). Any of these materials may be dispersed in a prepolymer before cross-linking into a final film.

The absorption sensitizer should minimally affect adhesion between layer 107 and the layers above and below. Surface-modified carbon-black pigments sold under the trade designation CAB-O-JET 200 by Cabot Corporation, Bedford, Mass. are found to minimally disrupt adhesion at loading levels providing adequate sensitivity for heating. The CAB-O-JET series of carbon black products are unique aqueous pigment dispersions made with novel surface modification technology, as, for example, described in U.S. Pat. Nos. 5,554,739 and 5,713,988. Pigment stability is achieved through ionic stabilization. No surfactants, dispersion aids, or polymers are typically present in the dispersion of the CAB-O-JET materials. Significantly, CAB-O-JET 200 also absorbs across the entire infrared spectrum, as well as across the visible and ultraviolet regions. BONJET BLACK CW-1, a surface-modified carbon-black aqueous dispersion available from Orient Corporation, Springfield, N.J., also resulted in adhesion to the hydrophilic layer 304 at the amounts required to give adequate sensitivity for ablation.

Other near-IR absorbers for absorbing layers based on polyvinyl alcohol include conductive polymers, e.g., polyanilines, polypyrroles, poly-3,4-ethylenedioxypyrroles, polythiophenes, and poly-3,4-ethylenedioxythiophenes. As polymers, these are incorporated into layer 304 in the form of dispersions, emulsions, colloids, etc. due to their limited solubility. Alternatively, they can be formed in situ from monomeric components included in layer 304 as cast (on substrate 302) or applied to layer 304 subsequent to the curing process—i.e., by a post-impregnation (or saturation) process; see, e.g., U.S. Pat. No. 5,908,705.

Certain inorganic absorbers, dispersed within the polymer matrix, also serve particularly well in connection with absorbing layers based on polyvinyl alcohol. These include TiON, TiCN, tungsten oxides of chemical formula WO₃₋ₓ, where 0<x<0.5 (with 2.7≦x≦2.9 being preferred) ; and vanadium oxides of chemical formula V₂O₅₋ₓ, where 0<x<1.0 (with V₆O₁₃ being preferred).

Suitable coatings may be formed by known mixing and coating methods, for example, wherein a base coating mix is formed by first mixing all the components, such as water; 2-butoxyethanol; AIRVOL 125 polyvinyl alcohol; UCAR WBV-110 vinyl copolymer; CYMEL 303 hexanethoxymethylmelamine crosslinking agent; and CAB-O-JET 200 carbon black (not including any crosslinking catalyst). To extend the stability of the coating formulation, a crosslinking agent, such as NACURE 2530, may be added subsequently to the base coating mix or dispersion just prior to the coating application. The coating mix or dispersion may be applied by any of the known methods of coating application, such as, for example, wire-wound rod coating, reverse-roll coating, gravure coating, or slot-die coating. After drying to remove the volatile liquids, a solid coating layer is formed.

2.4 Topmost Layer 110

The oleophilic topmost layer participates in printing and provides the requisite lithographic affinity difference with respect to substrate 102 and/or hydrophilic layer 105. The topmost layer 110 remains bonded to the absorbing layer 107 where not exposed to imaging radiation, and adsorbs ink as the image surface of the lithographic printing member 100. The surface layer preferably comprises an uncrosslinked polymeric material and a surfactant.

The surface layer is preferably coated onto the infrared absorbing layer using an organic solvent or mixture of organic solvents. The remaining layers are applied using aqueous solutions. The surface layer preferably comprises a novolak, a polyurethane resin or a terpolymer comprising vinyl chloride, vinyl acetate, and hydroxy alkyl acrylate, with a dry coating weight between 0.05 and 0.50 g/m². A preferred dry coating weight for the surface layer would be between 0.10 and 0.30 g/m². Other suitable (but less preferred) materials for layer 110 include polyvinyl butyral, cellulose acetate butyrate, cellulose acetate phthalate, and JAYLINK 106E (acrylamido-modified cellulose acetate butyrate).

In preferred embodiments, the durability and surface lubricity of the topmost layer is improved by the incorporation of a surfactant. These can include BYK 301, a silicone surface additive manufactured by BYK Chemie, or NOVEC FC-4432, fluorochemical surfactant manufactured by 3M. Typically, the surfactant represents 1 to 3% of the dry coating weight.

### 3. Imaging Techniques

FIGS. 2A and 2B show the consequences of imaging the printing member illustrated in FIG. 1. With reference to FIG. 2A, in the exposed area region 200, layer 107 absorbs the imaging pulse and converts it to heat. The heat diffuses through layer 107 and disrupts its polymeric structure and/or de-anchors it from underlying layer 105, substantially without ablation. In addition, layer 110 experiences the heat produced by layer 107 and, as a consequence, is also degraded substantially without ablation.

After imaging, the portions of layers 107, 110 that have received radiation are removed by cleaning with an aqueous fluid (e.g., tap water or or a mixture of water and a surfactant), which may occur prior to printing or during print “make ready.” In some embodiments, the printing member can be used on press immediately after being imaged without the need for a post-imaging processing step.

Printing with the printing member includes applying dampening solution to the plate followed by ink, which is thereby transferred in the imagewise lithographic pattern (created as described above) to a recording medium such as paper. The inking and transferring steps may be repeated a desired number of times, e.g., up to 70,000 or more times.

### EXAMPLES

Three substrates were prepared under different electrochemical graining conditions:

TABLE 1

| | Substrate Characteristics | | |
|---|---|---|---|
| | | | Surface |
| Variation | Ra | Rz | Volume |
| A | .29 μm | 4.8 μm | 17,680 μm³ |
| B | .43 μm | 6.5 μm | 10,030 μm³ |
| C | .20 μm | 3.0 μm | 9,156 μm³ |

Each substrate was subsequently coated with a hydrophilic polymer layer and an infrared absorbing layer on top of that. The hydrophilic layer was coated at an approximate thickness of 1.0 μm and at a dry coating weight of around 1.5 g/m². Polyvinyl alcohol resin represents the bulk of this layer (between 60 and 80%). A crosslinking agent, BACOTE 20 (ammonium zirconyl carbonate solution) was also included in the coating solution, estimated at 15 to 30% of the dry coating weight. The aqueous infrared absorbing layer was applied to the dry/cured hydrophilic layer and substrate at an approximate dry coat weight of 0.34 g/m². This coating layer contains an absorbing component (between 30 and 40% of the dry coat weight), water soluble cross-linkable binders and/or emulsions (approximately 50% of the dry coat weight) and melamine resins and an acid catalyst (between 4 and 6% of the dry coat weight).

All three coated plates were evaluated. Plates were first imaged on a KODAK TRENDSETTER at 13 watts/240 rpm, then processed through a PRESSTEK AS-34 AQUASCRUBBER filled with tap water (maintained at a temperature of 92-94° F.). Transport speed was set at 30 inches/min. The imaged and cleaned plates were examined and rated for cleanliness and the level of coating retention in laser-imaged areas.

TABLE 2
Substrate Variant
(See Table 1)

| A | B | C |
|---|---|---|
| 1 | 3 | 1 |

In Table 2, values range from 1 (visibly clean, no coating retention) to 5 (heavy coating retention). The results indicate that the characteristics of the grain will somewhat influence the imaging and cleaning characteristics of the plate. The preferred grain of substrate A results in a plate that is considered to be completely clean (no coating retention) after imaging and processing (as described above.) The “smoother” grain of substrate C, which clearly has the least amount of surface topography of the three grain samples, results in a plate with approximately the same level of coating retention as substrate A. Substrate B, which is a rougher and somewhat pitted grain with more of a detailed structure than that of substrate C, results in a plate that is mostly clean (visibly) but, upon closer examination, shows small black specks (coating retention) in the laser-imaged area.

A series of three different surface-layer coatings were prepared for evaluation on each of the coated substrates described above.

### Example 1

A surface layer comprising 1.5% ESTANE 5715 (polyester-type thermoplastic polyurethane resin manufactured by Lubrizol Advanced Materials, Inc) and 0.05% FC-4432 (NOVEC fluorosurfactant manufactured by 3M) in Dowanol PM. The resin was initially dissolved in Dowanol PM at approximately 10% solids. (This stock solution took several hours to prepare, using a relatively high mixing speed.) The stock solution was diluted down to approximately 1.5% with additional Dowanol PM and the FC-4432 was added in at approximately 0.05%. The solution was then mixed for 20 minutes before coating.

### Example 2

A surface layer comprising 1.5% VAGF (solution vinyl resin manufactured by Dow) and 0.05% FC-4432 was prepared. The resin was initially dissolved in Dowanol PMA at approximately 10% solids. (This stock solution took several hours to prepare, using a relatively high mixing speed.) The stock solution was diluted down to approximately 1.5% with Dowanol PM and the FC-4432 was added in at approximately 0.05%. The solution was then mixed for 20 minutes before coating.

### Example 3

A surface layer comprising 1.5% nitrocellulose resin and 0.05% FC-4432 was prepared. The nitrocellulose resin was obtained from Aldrich Chemical (“wetted” with 2-propanol at 30%.) A 10% solids stock solution was prepared by dissolving the “wetted” resin in Dowanol PM. This stock solution was further diluted down to 1.5% solids, using additional PM. The FC-4432 surfactant was added in at approximately 0.05%. The solution was then mixed for 20 minutes before coating.

A wire-wound coating rod (Meyer) was utilized to apply the coating of each of the examples. After coating application, all plates were dried at 250° F. for approximately 40 seconds (to eliminate solvent). The dry coating weight of each surface layer was estimated to be 0.18 g/m². Each of the test plates was imaged on a KODAK TRENDSETTER at the power settings listed in Table 3 below. Plates were then sent through a PRESSTEK AS-34 AQUASCRUBBER filled with tap water (maintained at a temperature of 92-94° F.). Transport speed was set at 30 inches/min. Upon evaluation, the following levels of visible coating retention were noted:

TABLE 3

| | Substrate Variant (See Table 1 | | |
|---|---|---|---|
| Surface Layer, | for Substrate Descriptions) | | |
| Imaging Power | A | B | C |
| Ex 1 - Estane Resin, 150 mJ | 1 | 3 | 3 |
| Ex 2 - VAGF Resin, 130 mJ | 1 | 4 | 4 |
| Ex 3 - Nitrocellulose, 130 mJ | 1 | 1 | 1 |

Once again, values range from 1 (visibly clean, no coating retention) to 5 (heavy coating retention). Results clearly demonstrate that A is the preferred substrate for this plate design. All surface layer coating solutions that incorporated the preferred grain structure can be imaged at low imaging energy (150 mJ or less) and water washed, with full release of the infrared absorbing layer and surface layer in the laser-imaged areas. Neither substrate B nor C is commercially acceptable. The laser-imaged areas of plate samples coated with the surface coating of Examples 1 and 2 cannot be fully cleaned on these substrates after imaging at preferred thermal energy levels.

All plate constructions (based on substrates A, B and C) coated with the nitrocellulose surface layer showed no visible coating retention after imaging and cleaning. The natural thermal instability of this resin contributes to its ability to be thermally imaged and cleaned on a wider latitude of substrate grain types. However, the instability of the nitrocellulose resin also makes this option difficult from a manufacturing standpoint. The resin is generally purchased “wet,” i.e., in a ˜30% solution in 2-propanol, and this solution is maintained (above 25%) for storage. This is because the dry resin powder is unstable and can be easily ignited by sparks. Any residual coating left to dry out in the manufacturing line or coating-preparation area can be a potential hazard. Handling issues are also a concern. (The preferred grade of nitrocellulose resin for use in the surface coating industry is closely related to the more highly nitrated form, which is used to make explosives.)

All substrate A examples were also subjected to a durability test. In this test, the fully-coated plate (unimaged and uncleaned) is rubbed back and forth (50 times) with a weighted ball-peen hammer (5 pounds) that has been covered with a moistened textured cloth (flat end). This test is used to simulate aggressive press wear conditions. The density of an untested area of the coated plate is measured (an average of 4-6 readings are taken) using an X-RITE SPECTRO densitometer and recorded. A similar set of measurements is taken in the area that has been rubbed. The average density of the rubbed area is then subtracted from the average density of the intact area and a value is obtained. The lower the value (or the lesser the loss in density), the more durable the plate will be. The higher the value (or the greater the loss in density), the less durable the plate will be.

The following results were obtained using substrate A coated with the hydrophilic and imaging layers described above, and the surface layers noted:

| | | | Example 3 as |
|---|---|---|---|
| No Surface Layer | Example 1 as | Example 2 as | Surface Layer |
| Above Imaging | Surface Layer | Surface Layer | (Nitrocellulose |
| Layer | (Estane Resin) | (Vinyl Resin) | Resin) |
| .30 | .19 | .12 | .14 |

The application of any of the example surface layers to a plate results in a significant improvement in durability for that plate.

Actual on-press testing of Example 2 on substrate A has demonstrated a minimum of twofold improvement in run length over a plate lacking the surface coating. Screens and fine lines appear to be much stronger, particularly in aggressive press situations (use of uncoated stock, inks with rough grinds). Specifically, a plate overcoated according to Example 2 did not any show any screen wear until 65-70,000 impressions. Additionally, the ink/water balance characteristics of the plate are also improved relative to a plate lacking the surface coating.

Although the present invention has been described with reference to specific details, it is not intended that such details should be regarded as limitations upon the scope of the invention, except as and to the extent that they are included in the accompanying claims.

What is claimed is:

1. A lithographic printing member comprising:
a substrate;
a hydrophilic layer disposed above the substrate;
an infrared-absorbing layer disposed above the hydrophilic layer; and
an ink-accepting surface layer disposed above the absorbing layer,
wherein the surface layer and the absorbing layer are unremovable by cleaning with an aqueous fluid until exposed to infrared imaging radiation, whereupon the surface layer and the absorbing layer are rendered removable by cleaning with an aqueous fluid where so exposed.

2. The printing member of claim 1 wherein the surface layer and the absorbing layer are substantially unablatable by exposure to infrared imaging radiation having a fluence of 180 mJ/cm² or less.

3. The printing member of claim 2 wherein the surface layer and the absorbing layer are at least 90% unablated by exposure to infrared imaging radiation having a fluence of 180 mJ/cm² or less.

4. The printing member of claim 2 wherein the surface layer and the absorbing layer are at least 98% unablated by exposure to infrared imaging radiation having a fluence of 180 mJ/cm² or less.

5. The printing member of claim 1 wherein the substrate is a grained metal sheet having (i) a roughness characterized by an Ra ranging from 0.2 to 0.45 μm and an Rz less than about 6 μm, and (ii) a surface volume greater than 15,000 μm³.

6. The printing member of claim 1 wherein the surface layer comprises a polymer and a surfactant.

7. The printing member of claim 7 wherein the surface layer is substantially uncrosslinked.

8. The printing member of claim 1 wherein the surface layer comprises at least one of (i) a novolak, (ii) a polyurethane resin, or (iii) a terpolymer comprising vinyl chloride, vinyl acetate, and hydroxyalkyl acrylate.

9. The printing member of claim 8 wherein the surface layer consists essentially of a novolak.

10. The printing member of claim 8 wherein the surface layer consists essentially of a polyurethane resin.

11. The printing member of claim 8 wherein the surface layer consists essentially of a terpolymer comprising vinyl chloride, vinyl acetate, and hydroxyalkyl acrylate.

12. The printing member of claim 1 wherein the absorbing layer comprises polyvinyl alcohol.

13. A method of imaging a lithographic printing member, the method comprising the steps of:
providing a lithographic printing member comprising a substrate, a hydrophilic layer disposed above the substrate, an infrared-absorbing layer disposed above the hydrophilic layer, and an ink-accepting surface layer disposed above the absorbing layer, wherein the surface layer and the absorbing layer are unremovable by subjection to an aqueous fluid until exposed to infrared imaging radiation;
exposing the printing member to infrared imaging radiation in an imagewise pattern to render the surface layer and the absorbing layer to be removable by an aqueous fluid where so exposed; and
subjecting the surface layer to an aqueous fluid to thereby remove only exposed portions of the surface layer and the absorbing layer.

14. The method of claim 13 wherein the surface layer and the absorbing layer are substantially unablated by exposure to infrared imaging radiation.

15. The method of claim 14 wherein the surface layer and the absorbing layer are at least 90% unablated by exposure to infrared imaging radiation.

16. The method of claim 14 wherein the surface layer and the absorbing layer are at least 98% unablated by exposure to infrared imaging radiation.

17. The method of claim 13 wherein the infrared imaging radiation has a fluence of 180 mJ/cm² or less.

18. The method of claim 13 wherein the substrate is a grained metal sheet having (i) a roughness characterized by an Ra ranging from 0.2 to 0.45 μm and an Rz less than about 6 μm, and (ii) a surface volume greater than 15,000 μm³.

19. The method of claim 13 wherein the surface layer comprises a polymer and a surfactant.

20. The method of claim 19 wherein the surface layer is substantially uncrosslinked.

21. The method of claim 13 wherein the surface layer comprises at least one of (i) a novolak, (ii) a polyurethane resin, or (iii) a terpolymer comprising vinyl chloride, vinyl acetate, and hydroxyalkyl acrylate.

22. The method of claim 21 wherein the surface layer consists essentially of a novolak.

23. The method of claim 21 wherein the surface layer consists essentially of a polyurethane resin.

24. The method of claim 21 wherein the surface layer consists essentially of a terpolymer comprising vinyl chloride, vinyl acetate, and hydroxyalkyl acrylate.

25. The method of claim 13 wherein the absorbing layer comprises polyvinyl alcohol.

26. The method of claim 13 wherein the aqueous fluid is tap water.

27. The method of claim 13 wherein the aqueous fluid is a mixture of water and a surfactant.
